(19) United States
(12) Patent Application Publication
(10) Pub. No.: US 2026/0324176 A1
(43) Pub. Date: Oct. 15, 2026

(54) FLIP MICRO-LED DISPLAY CHIP PACKAGE AND PACKAGING METHOD FOR THE SAME

(71) Applicant: Powertech Technology Inc., Hukou Township (TW)

(72) Inventors: Hung-Hsin HSU, Hukou Township (TW); Chun-Wei PAN, Hukou Township (TW)

(73) Assignee: Powertech Technology Inc., Hukou Township (TW)

(21) Appl. No.: 19/306,858

(22) Filed: Aug. 21, 2025

(30) Foreign Application Priority Data
Apr. 15, 2025 (TW) 114114272

(51) Int. Cl. H10H 29/85; H10H 29/01; H10H 29/24

(52) U.S. Cl. CPC H10H 29/857; H10H 29/0364; H10H 29/24

(57) ABSTRACT

A flip micro-LED display chip package has a first substrate, a second substrate, multiple inner connection elements, and multiple outer connection elements. The first substrate has at least one emitting hole and at least one micro-LED display chip bonded onto the first substrate. The second substrate has multiple metal pads arranged on a first surface of the second substrate and connecting to multiple metal pads via the inner connection elements. The outer connection elements connect respectively to multiple metal pads arranged on a second surface of the second substrate.

### CROSS-REFERENCE TO RELATED APPLICATIONS

This application is based upon and claims priority under 35 U.S.C. 119 from Taiwan Patent Application No. 114114272 filed on Apr. 15, 2025, which is hereby specifically incorporated herein by this reference thereto.

### BACKGROUND OF THE INVENTION

### 1. Field of the Invention

The present invention relates to a chip package, and more particularly to a flip micro-LED display chip package.

### 2. Description of the Prior Arts

With reference to FIG. 5, a conventional flip micro-LED display chip package for a display for consumer electronics comprises a substrate 70, a micro-LED display chip 80 mounted on the substrate 70, and a control chip 90.

The substrate 70 has a first surface 71 and a second surface 72 opposite to each other. The first surface 71 has multiple first contact pads 711 and multiple first wires 712 connecting to the first contact pads 711. The second surface 72 has multiple second contact pads 721, multiple third contact pads 722, and multiple second circuits 723 connecting to the second contact pads 721 and the third contact pads 722. The second contact pads 721 are soldered with the control chip 90, and the third contact pads 722 are formed with solder balls 91.

One of the surfaces of the micro-LED display chip 80 has an emitting area 81 and non-emitting area 82. The emitting area 81 has multiple micro-LED elements 83. The non-emitting area 82 surrounds the emitting area 81 and has multiple first chip pads 84 formed thereon. With the conventional flip semiconductor chip packaging method, the first chip pads 84 have to be faced and be respectively soldered to the first contact pads 711 on the first surface 71 of the substrate 70. However, the micro-LED elements 83 mounted on a same surface with the first contact pads 711 also face to the substrate 70 and cannot emit light outward.

Therefore, as shown in FIG. 5, the micro-LED display chip 80 further has multiple through silicon vias (TSV) 85, and multiple second chip pads 86 are formed on the other surface and connect electrically to the first chip pads 84 via the TSV 85. Accordingly, as shown in the Figure, the second chip pads 86 are faced and soldered respectively with the first contact pads 711 on the first surface 71 of the substrate 70. Thus, the first chip pads 84 connect electrically to the first contact pads 711 via the TSV 85 and the second chip pads 86, such that the micro-LED elements 83 can emit light outward.

That is, when the conventional micro-LED display chip 80 is applied with the flip-chip bonding technology, multiple TSV 85 have to be formed. However, this will damage and reduce the yield of the conventional micro-LED display chip 80. Therefore, the use of flip-chip bonding technology for the micro-LED display chip 80 still requires further improvement.

To overcome the shortcomings, the present invention provides a flip micro-LED display chip package to mitigate or to obviate the aforementioned problems.

### SUMMARY

The objective of the present invention is to provide a flip micro-LED display chip package without through silicon vias and a packaging method for the same.

The present invention provides a flip micro-LED display chip package has
a first substrate comprising at least one emitting hole, multiple first contact pads, and multiple metal pads, wherein the first contact pads and the first metal pads are formed on one surface of the first substrate;
at least one micro-LED display chip bonded onto the first substrate, and one surface of each one of the at least one micro-LED display chip comprising
   an emitting area aligning with one of the at least one emitting hole in the first substrate and comprising multiple micro-LED elements; and
   a non-emitting area arranged around the emitting area and comprising multiple first chip pads connecting respectively to the first contact pads on the first substrate;
a second substrate comprising
   a first surface having multiple second metal pads corresponding to the first metal pads on the first substrate in position; and
   a second surface being opposite the first surface and having multiple third metal pads;
multiple inner connection elements connecting to the first metal pads and the second metal pads; and
multiple outer connection elements connecting respectively to the third metal pads.

With such an arrangement, a micro-LED display chip shipped from a chip factory can be directly applied to the flip micro-LED display chip package in accordance with the present invention, aligns with the emitting hole in the first substrate to bond the display chip onto the first substrate. The micro-LED display chip connects to the second substrate via the inner connection elements, and multiple outer connection elements are arranged on the second substrate. Accordingly, a flip micro-LED display chip package is provided. Therefore, forming multiple through silicon vias for the bonding process is unnecessary to ensure the yield of manufacturing the chip package.

To achieve the aforementioned objective, the present invention also provides a packaging method for a flip micro-LED display chip package comprising steps of:
(a) preparing a first substrate and a second substrate, wherein the first substrate comprises at least one emitting hole, at least one micro-LED display chip bonded on the first substrate, and multiple inner connection elements arranged around the at least one micro-LED display chip, each one of the at least one micro-LED display chip having an emitting area aligning with one of the at least one emitting hole, a first surface of the second substrate has multiple second metal pads, and a second surface of the second substrate has multiple third metal pads;
(b) facing the inner connection elements on the first substrate to the first surface of the second substrate and respectively aligning with and connecting to the second metal pads on the first surface; and
(c) turning the first substrate and the second substrate upside down to make the third metal pads on the second substrate face upward, and connecting multiple outer connection elements with the third metal pads.

Based on the foregoing description, in the flip micro-LED display chip package method in accordance with the present invention, a first substrate and a second substrate are provided, wherein at least one micro-LED display chip is flip-chip bonded onto the first substrate. The at least one micro-LED display chip aligns with at least one emitting hole. The first substrate connects to the second substrate via the inner connection elements. Multiple outer connection elements are then arranged on the second substrate, such that the flip micro-LED display chip package are formed. Accordingly, a micro-LED display chip shipped from chip factories can be directly applied in the present invention, and forming multiple through silicon vias for the bonding process is unnecessary to ensure the yield of manufacturing the chip package.

### BRIEF DESCRIPTION OF THE DRAWINGS

FIG. 1 is a partial cross-sectional side view of a first embodiment of a flip micro-LED display chip package in accordance with the present invention;

FIG. 2 is a partial cross-sectional side view of a second embodiment of a flip micro-LED display chip package in accordance with the present invention;

FIGS. 3A to 3F show a first embodiment of multiple steps of a packaging method in accordance with the present invention for packaging the second embodiment of the flip micro-LED display chip package in FIG. 2;

FIGS. 4A to 4F show a second embodiment of multiple steps of a packaging method in accordance with the present invention for packaging the second embodiment of the flip micro-LED display chip package in FIG. 2; and

FIG. 5 is a partial cross-sectional side view of a conventional flip micro-LED display chip package.

### DETAILED DESCRIPTION OF THE EMBODIMENTS

The present invention is related to an improved flip micro-LED display chip package. Other objectives, advantages and novel features of the invention will become more apparent from the following detailed description when taken in conjunction with the accompanying drawings.

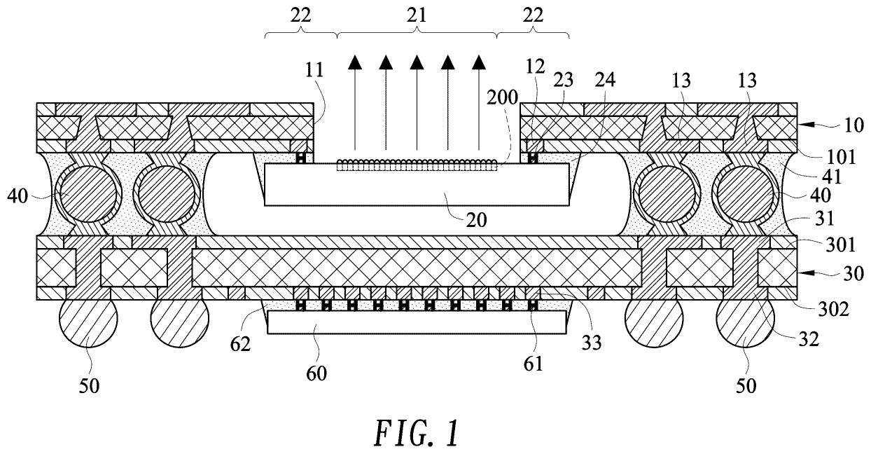

With reference to FIG. 1, a first embodiment of a flip micro-LED display chip package in accordance with the present invention comprises a first substrate 10, at least one micro-LED display chip 20, a second substrate 30, multiple inner connection elements 40, and multiple outer connection elements 50. In addition, the package may further comprise at least one control chip 60.

The first substrate 10 comprises at least one emitting hole 11, multiple first contact pads 12, and multiple first metal pads 13. The first contact pads 12 and the first metal pads 13 are arranged on a surface 101 of the first substrate 10. In this embodiment, the substrate 10 includes one emitting hole 11, and the first contact pads 12 are located around two opposite sides or four sides of the emitting hole 11. The first metal pads 13 are arranged along two opposite sides or four sides of the first substrate 10 and are away from the sides of the emitting hole 11.

The micro-LED display chip 20 is flip-chip bonded to the first substrate 10. One surface of the micro-LED display chip 20 has an emitting area 21 and non-emitting area 22 outside the emitting area 21. The emitting area 21 faces the emitting hole 11 in the first substrate 10 and multiple micro-LED elements 200 are mounted in the emitting area 21. Multiple first chip pads 23 are formed in the non-emitting area 22. The first chip pads 23 are connect respectively to the first contact pads 12 on the first substrate 10, and the connection positions of the first chip pads 23 and the first contact pads 12 are covered by a first underfill 24.

The second substrate 30 comprises a first surface 301 and a second surface 302 opposite to each other. Multiple second metal pads 31 corresponding respectively to the first metal pads 13 on the first substrate 10 in position are formed on the first surface 301. Multiple third metal pads 32 are formed on the second surface 302. In addition, multiple second contact pads 33 are further formed on the second surface 302. The third metal pads 32 are located around the second contact pads 33.

The inner connection elements 40 connect to the first metal pads 13 and the second metal pads 31. The inner connection elements 40, the first metal pads 13, and the second metal pads 31 are covered by an insulating encapsulation 41. In this embodiment, each inner connection element 40 is a copper core ball (Cu core ball) or may be a copper pillar or a solder ball.

The multiple outer connection elements 50 connect respectively to the third metal pads 32. In this embodiment, each outer connection element 50 is the solder ball and is applied to be soldered onto an outer circuit board(not shown).

The control chip 60 comprises multiple second chip pads 61. The second chip pads 61 connect respectively to the second contact pads 33 on the second surface 302 of the second substrate 30. The connection positions of the second chip pads 61 and the second contact pads 33 are covered by a second underfill 62. The outer connection elements 50 are arranged around the control chip 60.

As aforementioned, the first chip pads 23 on the micro-LED display chip 20 directly connect to the first contact pads 12 on the first substrate 10 via the first chip pads 23 to flip-chip bonded on the first substrate 10. Thus, forming multiple through silicon vias in the display chip 20 is unnecessary. In addition, with the connections between inner connection elements 40 and the second substrate 30, the outer connection elements 50 are arranged on the second substrate 30 and directly connect electrically to an outer circuit board.

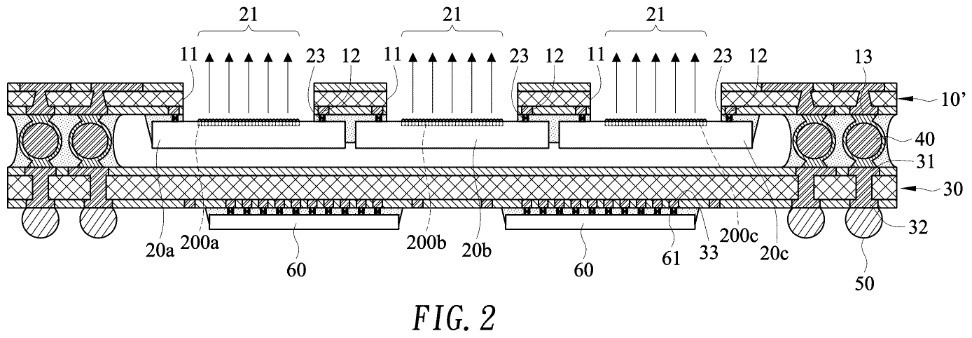

With reference to FIG. 2, a second embodiment of a flip micro-LED display chip package in accordance with the present invention has a structure similar to that in the first embodiment except that the first substrate 10 has multiple emitting holes 11 and multiple micro-LED display chips 20a, 20b, 20c those emit lights in different colors. As shown in FIG. 2, this embodiment has three emitting holes 11. A micro-LED display chip 20a having an LED element 200a for emitting red light, a micro-LED display chip 20b having an LED element 200b for emitting blue light, and a micro-LED display chip 20c having an LED element 200c for emitting green light are bonded onto the first substrate 10. The first contact pads 12 are arranged adjacent to sides of the emitting hole 11 to connect to the first chip pads 23 on the corresponding micro-LED display chip 20a, 20b, 20c. In addition, in this embodiment, multiple control chips are provided, such that the second contact pads 33 on the second substrate 30 corresponding to different control chips 60 are increased and connect to the second chip pads 61 on the control chips 60. Therefore, the embodiment of the flip micro-LED display chip package emits multiple colors of light and white light.

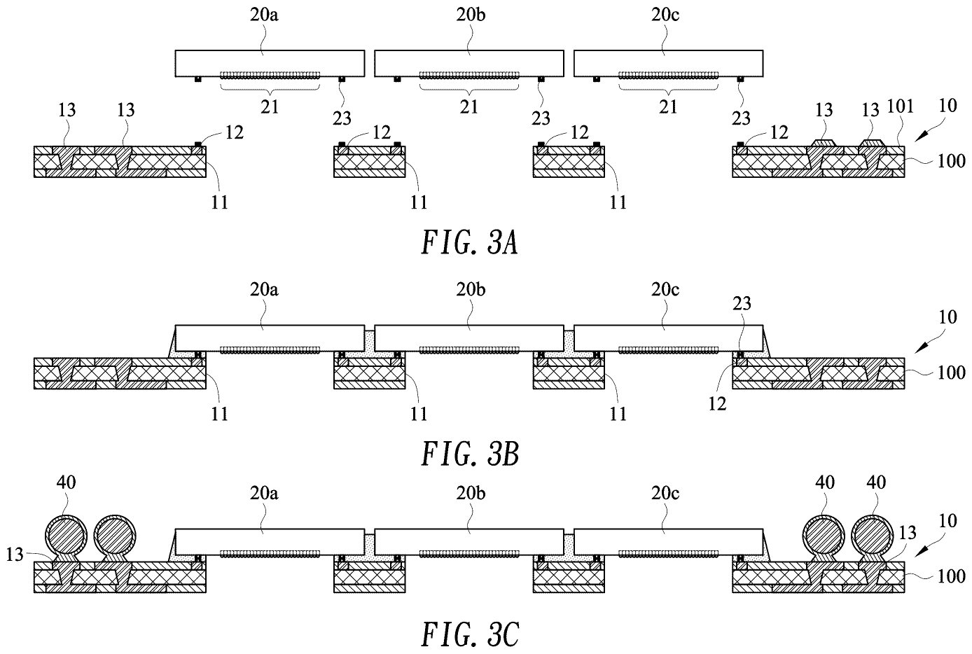

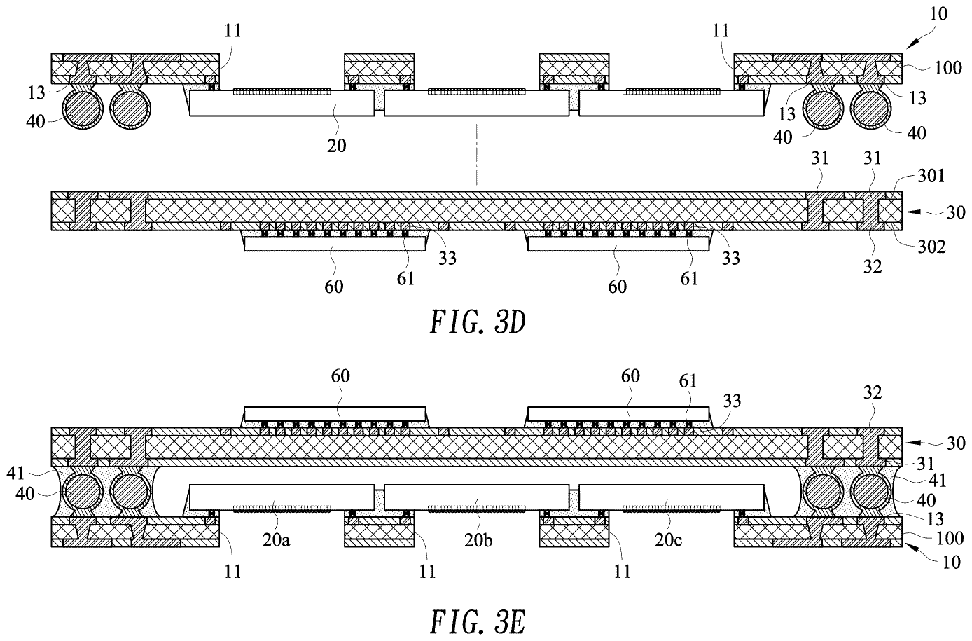

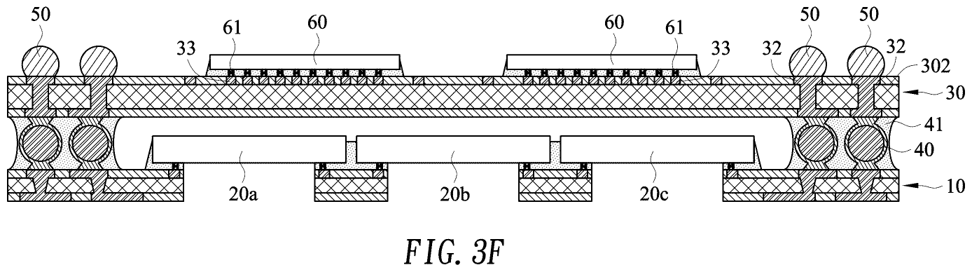

With reference to FIGS. 3A to 3F, a first embodiment of a packaging method for the second embodiment of the flip micro-LED display chip package shown in FIG. 2 comprises steps (a) to (c).

In step (a), with reference to FIG. 3D, a first substrate 10 and a second substrate 30 are prepared. Multiple emitting holes 11 are formed in the first substrate 10. Multiple micro-LED display chips 20a, 20b, 20c are flip-chip bonded onto the first substrate 10 and multiple inner connection elements 40 arranged around the micro-LED display chips 20a, 20b, 20c. The emitting areas of the micro-LED display chips 20a, 20b, 20c face the emitting holes 11, respectively. Multiple second metal pads 31 are arranged on the first surface 301 of the second substrate 30. Multiple third metal pads 32 are arranged on the second surface 302 of the second substrate 30. In addition, multiple second metal pads 31 may further be arranged on the second surface 302 for connecting to the second chip pads 61 on the control chip 60. Accordingly, the control chip 60 are bonded onto the second surface 302 of the second substrate 30.

In this embodiment, the first substrate 10 is made by the steps shown in FIGS. 3A to 3C. With reference to FIG. 3A, a base board 100 is prepared. Multiple first contact pads 12 and multiple first metal pads 13 are formed on one of the surfaces of the base board 100. The first metal pads 13 are arranged around the first contact pads 12. Multiple emitting holes 11 are then formed through the base board 100, and the first contact pads 12 are arranged on sides of the emitting holes 11. With reference to FIG. 3B, the emitting area of the micro-LED display chips 20a, 20b, 20c align respectively with the emitting holes 11. The first chip pads 23 on the chips 20a, 20b, 20c connect to the first contact pads 12, thereby the chips 20a, 20b, 20c are flip-chip bonded onto the base board 100.

In the step (b), with reference to FIG. 3D, the inner connection elements 40 on the first substrate 10 are faced the first surface 301 of the second substrate 30 and align with and connect to the second metal pads 31 on the first surface 301, respectively.

In the step (c), with reference to FIG. 3E, the first substrate 10 and the second substrate 30 are turned upside down, such that the third metal pads 32 on the second substrate 30 face upward. With reference to FIG. 3F, multiple outer connection elements 50 are formed on the third metal pads 32.

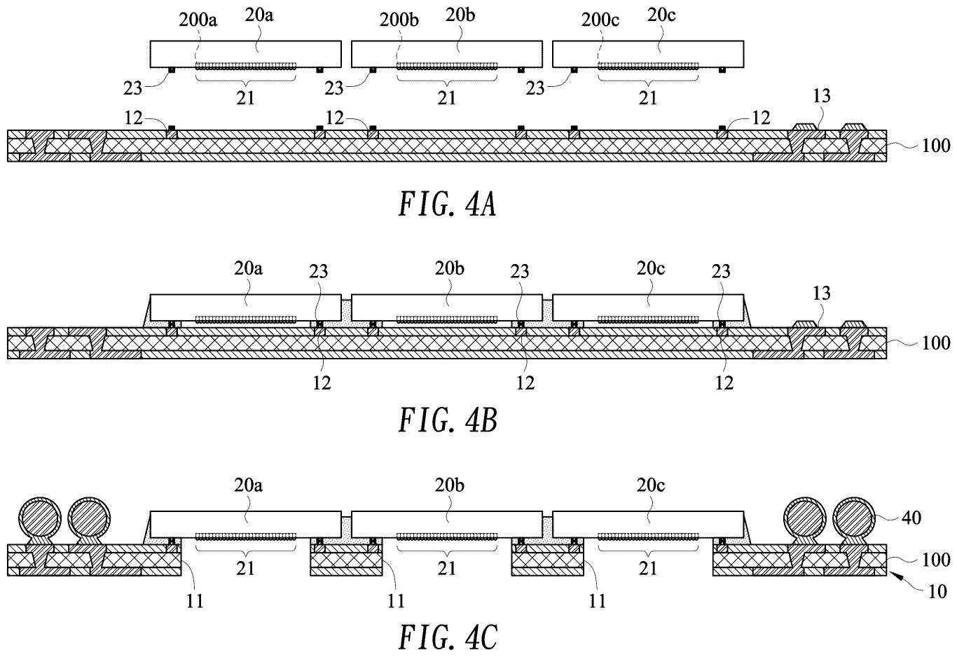

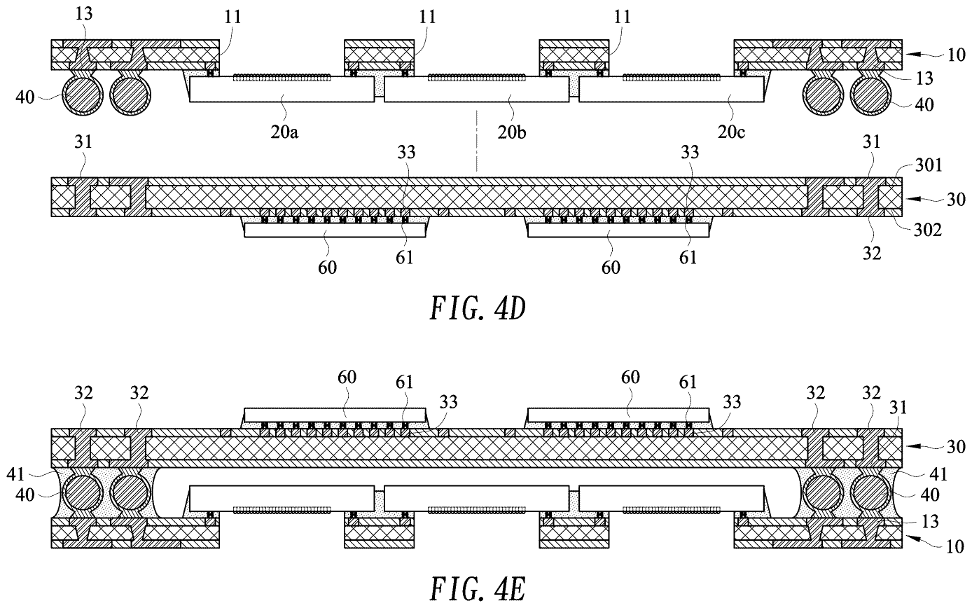

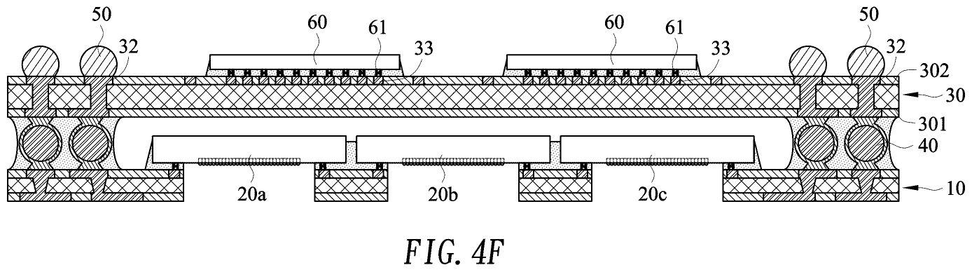

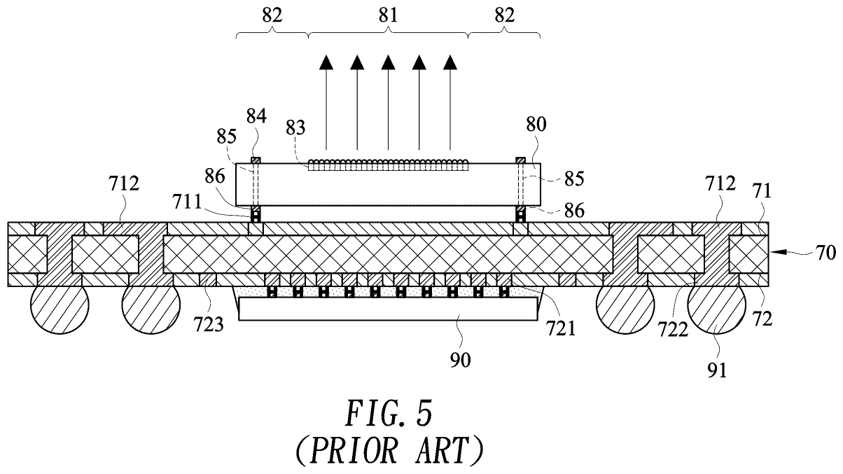

With reference to FIGS. 4A to 4F, a second embodiment of a packaging method for the second embodiment of the flip micro-LED display chip package shown in FIG. 2 comprises steps (a) to (c). The steps (b) and (c) shown in FIGS. 4D to 4F are the same as that shown in FIGS. 3D to 3F, except that the steps for forming the first substrate 10 are different. With reference to FIG. 4A, a base board 100 is prepared. Multiple first contact pads 12 and multiple first metal pads 13 are formed on one surface of the base board 100. The first metal pads 13 are arranged around the first contact pads 12. With reference to FIG. 4B, the emitting area of the micro-LED display chips 20a, 20b, 20c faces the base board 100. With reference to FIG. 4C, multiple emitting holes 11 are formed through the base board 100 at positions respectively aligning with the emitting area 21 of the micro-LED display chips 20a, 20b, 20c are. Accordingly, the emitting area 21 of the micro-LED display chips 20a, 20b, 20c align respectively with the emitting holes 11. Multiple inner connection elements 40 connect to the first metal pads 13 on the base board 100.

Accordingly, the method for packaging the flip micro-LED display chip package in accordance with the present invention comprises steps of preparing a first and a second substrates, wherein at least one micro-LED display chip is bonded onto the first substrate. The at least one micro-LED display chip aligns with at least one emitting hole. The first substrate connects to the second substrate via the inner connection elements. Multiple outer connection elements are then arranged on the second substrate, such that the flip micro-LED display chip package are formed. Therefore, a micro-LED display chip shipped from chip factories can be directly applied in the present invention, and forming multiple through silicon vias for the bonding process is unnecessary to ensure the yield of manufacturing the chip package.

Even though numerous characteristics and advantages of the present invention have been set forth in the foregoing description, together with details of the structure and features of the invention, the disclosure is illustrative only. Changes may be made in the details, especially in matters of shape, size, and arrangement of parts within the principles of the invention to the full extent indicated by the broad general meaning of the terms in which the appended claims are expressed.

What is claimed is:

1. A flip micro-LED display chip package comprising
a first substrate comprising at least one emitting hole, multiple first contact pads, and multiple first metal pads, wherein the first contact pads and the first metal pads are formed on one of multiple surfaces of the first substrate;
at least one micro-LED display chip flip-chip bonded onto the first substrate, and one surface of each one of the at least one micro-LED display chip comprising
an emitting area aligning with one of the at least one emitting hole in the first substrate and comprising multiple micro-LED elements; and
a non-emitting area arranged around the emitting area and comprising multiple first chip pads connecting respectively to the first contact pads on the first substrate;
a second substrate comprising
a first surface having multiple second metal pads corresponding to the first metal pads on the first substrate in position; and
a second surface being opposite the first surface and having multiple third metal pads;
multiple inner connection elements connecting to the first metal pads and the second metal pads; and
multiple outer connection elements connecting respectively to the third metal pads.

2. The chip package as claimed in claim 1, wherein
the first substrate comprises three emitting holes, and the first contact pads are located around the three emitting holes; and
the at least one micro-LED display chip comprises three micro-LED display chips respectively emitting lights in three different colors, aligning respectively with the three emitting holes, and the first chip pad on each micro-LED display chip connects to the first contact pads arranged around a corresponding one of the emitting holes.

3. The chip package as claimed in claim 1, wherein
the second surface of the second substrate further comprises multiple second contact pads; and
the chip package further comprises at least one control chip, and each one of the at least one control chip comprises multiple second chip pads connecting respectively to the second contact pads.

4. The chip package as claimed in claim 3, wherein the first metal pads are located around two opposite sides or four sides of the emitting holes.

5. The chip package as claimed in claim 4, wherein
the first metal pads are arranged along two opposite sides or four sides of the first substrate; and
the second metal pads are arranged along two opposite sides or four sides of the second substrate.

6. The chip package as claimed in claim 3, wherein the third metal pads on the second substrate are arranged around the second contact pads.

7. The chip package as claimed in claim 3, wherein
multiple connection positions of the first chip pads and the first contact pads are covered by a first underfill; and
multiple connection positions of the second chip pads and the second contact pads are covered by a second underfill.

8. The chip package as claimed in claim 3, wherein
each one of the inner connection elements is a copper core ball (Cu core ball), a copper pillar or a solder ball; and
the inner connection elements, the first metal pads, and the second metal pads are covered by an insulating encapsulation.

9. A packaging method for a flip micro-LED display chip package comprising steps of:
(a) preparing a first substrate and a second substrate, wherein the first substrate comprises at least one emitting hole, at least one micro-LED display chip flip-chip bonded on the first substrate, and multiple inner connection elements arranged around the at least one micro-LED display chip, each one of the at least one micro-LED display chip having an emitting area aligning with one of the at least one emitting hole, wherein the second substrate having a first surface on which multiple second metal pads are formed, and a second surface on which multiple third metal pads are formed;
(b) facing the inner connection elements on the first substrate to the first surface of the second substrate and respectively aligning with and connecting to the second metal pads on the first surface; and
(c) turning the first substrate and the second substrate upside down to make the third metal pads on the second substrate face upward, and connecting multiple outer connection elements with the third metal pads.

10. The method as claimed in claim 9, wherein in the step (a), the first substrate is formed by following steps of:
(a1) preparing a base board, wherein one of multiple surfaces of the base board has multiple first contact pads and multiple first metal pads, and the first metal pads are arranged around the first contact pads;
(a2) forming the at least one emitting hole through the base board, wherein the first contact pads are arranged along sides of the at least one emitting hole;
(a3) aligning the at least one micro-LED display chip respectively with the at least one emitting hole, and connecting multiple first chip pads on the first contact pads of the at least one micro-LED display chip to flip-chip bond the at least one micro-LED display chip onto the base board; and
(a4) connecting multiple inner connection elements with the first metal pads on the first substrate.

11. The method as claimed in claim 9, wherein in the step (a), the first substrate is formed by the following steps of:
(a1) preparing a base board, wherein one surface of the base board having multiple first contact pads and multiple first metal pads, and the first metal pads are arranged around the first contact pads;
(a2) connecting multiple first chip pads on the at least one micro-LED display chip to the first contact pads on the base board to flip-chip bond the at least one micro-LED display chip onto the base board;
(a3) forming the at least one emitting hole through the base board by cutting the other surface of the base board at least one position aligning respectively with the at least one micro-LED display chip; and
(a4) connecting multiple inner connection elements to the first metal pads on the first substrate.

12. The method as claimed in claim 10, wherein in the step (a), at least one control chip is flip-chip bonded to the third metal pads on the second surface of the second substrate.

13. The method as claimed in claim 11, wherein in the step (a), at least one control chip is flip-chip bonded to the third metal pads on the second surface of the second substrate.

14. The method as claimed in claim 12, wherein in the step (c), the outer connection elements are arranged around the at least one control chip.

15. The method as claimed in claim 13, wherein in the step (c), the outer connection elements are arranged around the at least one control chip.

16. The method as claimed in claim 13, wherein
multiple connection positions of the first chip pads and the first contact pads are covered by a first underfill; and
multiple connection positions of the second chip pads and the second contact pads are covered by a second underfill.

17. The method as claimed in claim 10, wherein
each one of the inner connection elements is a copper core ball (Cu core ball), a copper pillar or a solder ball; and
the inner connection elements, the first metal pads, and the second metal pads are covered by an insulating encapsulation.

18. The method as claimed in claim 11, wherein
each one of the inner connection elements is a copper core ball (Cu core ball), a copper pillar or a solder ball; and
the inner connection elements, the first metal pads, and the second metal pads are covered by an insulating encapsulation.

19. The method as claimed in claim 14, wherein
each one of the inner connection elements is a copper core ball (Cu core ball), a copper pillar or a solder ball; and
the inner connection elements, the first metal pads, and the second metal pads are covered by an insulating encapsulation.

20. The method as claimed in claim 15, wherein
each one of the inner connection elements is a copper core ball (Cu core ball), a copper pillar or a solder ball; and
the inner connection elements, the first metal pads, and the second metal pads are covered by an insulating encapsulation.
